(19) United States
(12) Patent Application Publication
(10) Pub. No.: US 2010/0148862 A1
(43) Pub. Date: Jun. 17, 2010

(54) METHOD AND APPARATUS FOR ENHANCING PERFORMANCE OF DOHERTY POWER AMPLIFIER

(75) Inventor: Young-Yoon WOO, Suwon-si (KR)

Correspondence Address: Jefferson IP Law, LLP, 1130 Connecticut Ave., NW, Suite 420, Washington, DC, 20036, US

(73) Assignee: SAMSUNG ELECTRONICS CO. LTD., Suwon-si (KR)

(21) Appl. No.: 12/627,371

(22) Filed: Nov. 30, 2009

(30) Foreign Application Priority Data
Dec. 16, 2008 (KR) 10-2008-0128140

(51) Int. Cl. H03F 3/68

(52) U.S. Cl. 330/124 R

(57) ABSTRACT

An apparatus and method for enhancing performance of a Doherty power amplifier are provided. The method includes a signal separation unit for generating a first input signal serving as an input signal of a carrier power amplifier using an input signal and a second input signal serving as an input signal of a peaking power amplifier using the input signal, in which the first input signal is different from the second input signal.

### PRIORITY

This application claims the benefit under 35 U.S.C. §119(a) of a Korean patent application filed in the Korean Intellectual Property Office on Dec. 16, 2008 and assigned Serial No. 10-2008-0128140, the entire disclosure of which is hereby incorporated by reference.

### BACKGROUND OF THE INVENTION

1. Field of the Invention

The present invention relates to a method and an apparatus for enhancing performance of a Doherty power amplifier. More particularly, the present invention relates to Doherty power amplifier for providing an input signal corresponding to each characteristic of a carrier power amplifier and a peaking power amplifier.

2. Description of the Related Art

In general, a Doherty power amplifier is an amplifier used for a high-efficiency modulation scheme of a high-power transmitter and can enhance anode efficiency through a combination of a class B amplifier, a class C amplifier and an impedance inverting circuit.

FIG. 1 is a diagram illustrating a conventional Doherty power amplifier.

Referring to FIG. 1, the Doherty power amplifier 100 includes an input separation unit 105, a carrier power amplifier 110, a peaking power amplifier 115, and a combiner 120.

The input separation unit 105 separates an input signal to generate two identical signals and outputs the two identical signals to the carrier power amplifier 110 and the peaking power amplifier 115, respectively. The carrier power amplifier 110 uses a relatively high input Direct Current (DC) bias. The peaking power amplifier 115 uses relatively low DC bias. Each of the carrier power amplifier 110 and peaking power amplifier 115 amplifies the input signal to correspond to a preset amplification gain to output the amplified input signal to the combiner 120. The combiner 120 combines an output signal of the carrier power amplifier 110 and the peaking power amplifier 115.

FIG. 2 is a graph illustrating an ideal input/output signal of a conventional Doherty power amplifier.

Referring to FIG. 2, if the input signal is less than a threshold level, that is, if a normalized input signal is less than 0.25, the peaking power amplifier 115 turns off and is not operated, and only the carrier power amplifier 110 turns on and is operated. Meanwhile, if the input signal is equal to or higher than a threshold level, that is, if a normalized input signal is equal to or higher than 0.25, the carrier power amplifier 110 and the peaking power amplifier 115 turn on at the same time. That is, the normalized input signal of 0.25 or higher is separated through the input separation unit 105 to be two identical signals. Each of the two identical signals are input to the carrier power amplifier 110 and the peaking power amplifier 115, respectively, amplified corresponding to the corresponding bias, and output to the combiner 120. The combiner 120 combines the output signal of the carrier power amplifier 110 and the peaking power amplifier 115.

As described above, the Doherty power amplifier 100 uses the carrier power amplifier 110 and the peaking power amplifier 115 which are operated in the input signal of a different level, respectively, so that it is possible to amplify the signal with high efficiency in a wide input band.

In the Doherty power amplifier 100, the carrier power amplifier 110 and the peaking power amplifier 115 use the identical input signal, but have characteristics of different Amplitude Modulation (AM) and Phase Modulation (PM). This is because the carrier power amplifier 110 uses a relatively high input DC bias and the peaking power amplifier 115 uses a relatively low input DC bias.

FIG. 3 is a graph illustrating an actual input/output signal of a conventional Doherty power amplifier.

Referring to FIG. 3, the carrier power amplifier 110 and the peaking power amplifier 115 use the different input DC bias so that the peaking power amplifier 115 has lower gain in comparison with the carrier power amplifier 110. Therefore, in the normalized input signal of the highest level, the output level of the peaking power amplifier 115 becomes lower than the ideal output level so that the combined signal of the output signal of the carrier power amplifier 110 and the output signal of the peaking power amplifier 115 has an undesirable distortion property.

Therefore, a need exists for a method and apparatus for enhancing performance of a Doherty power amplifier.

### SUMMARY OF THE INVENTION

An aspect of the present invention is to address at least the above-mentioned problems and/or disadvantages and to provide at least the advantages described below. Accordingly, an aspect of the present invention is to provide a method and an apparatus for enhancing performance of a Doherty power amplifier.

Another aspect of the present invention is to provide a method and an apparatus for providing a different input signal according to each characteristic of a carrier power amplifier and a peaking power amplifier to improve an output level of a Doherty power amplifier.

Still another aspect of the present invention is to provide a method and an apparatus for independently and linearly compensating each of a carrier power amplifier and a peaking power amplifier in a Doherty power amplifier.

In accordance with an aspect of the present invention, an apparatus for enhancing performance of a Doherty power amplifier is provided. The apparatus includes a signal separation unit for generating a first input signal serving as an input signal of a carrier power amplifier using an input signal and a second input signal serving as an input signal of a peaking power amplifier using the input signal, wherein the first input signal is different from the second input signal.

In accordance with another aspect of the present invention, a method for enhancing performance of a Doherty power amplifier is provided. The method includes generating a first input signal serving as an input signal of a carrier power amplifier using an input signal and generating a second input signal serving as an input signal of a peaking power amplifier using the input signal, wherein the first input signal is different from the second input signal.

In accordance with still another aspect of the present invention, an apparatus including a digital block for linearizing in a Doherty power amplifier is provided. The digital block includes a signal separation unit for generating an input signal corresponding to characteristics of a carrier power amplifier and a peaking power amplifier, and for outputting a first input signal to the carrier power amplifier and a second input signal to the peaking power amplifier, a carrier linearizer for independently linearizing the output of the carrier power amplifier, a peaking linearizer for independently linearizing the output of the peaking power amplifier, and a compensator for determining a first linear compensation value for compensation of linearity of the carrier power amplifier and a second linear compensation value for the compensation of linearity of the peaking power amplifier.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a diagram illustrating a conventional Doherty power amplifier;

FIG. 2 is a graph illustrating an ideal input/output signal of a conventional Doherty power amplifier;

FIG. 3 is a graph illustrating an actual input/output signal of a conventional Doherty power amplifier;

FIG. 4 is a diagram illustrating a Doherty power amplifier according to an exemplary embodiment of the present invention;

FIG. 5 is a graph illustrating an output signal of a signal separation unit according to an exemplary embodiment of the present invention;

FIG. 6 is a diagram illustrating a Doherty power amplifier according to an exemplary embodiment of the present invention;

FIG. 7 is a flowchart illustrating steps for obtaining a carrier linear compensation value in a digital block according to an exemplary embodiment of the present invention; and

FIG. 8 is a flowchart illustrating steps for obtaining a peaking linear compensation value in a digital block according to an exemplary embodiment of the present invention.

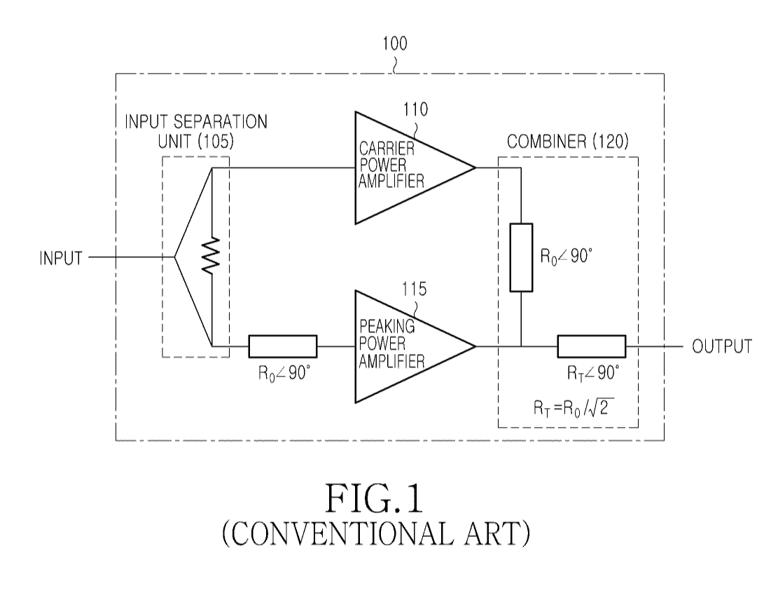

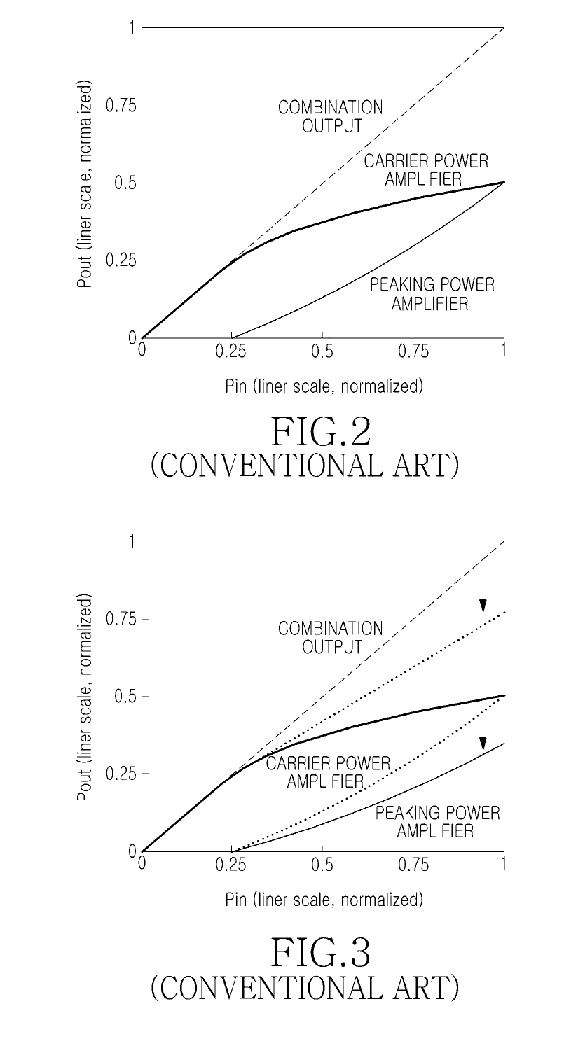

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Exemplary embodiments of the present invention provide a Doherty power amplifier for providing an input signal corresponding to each characteristic of a carrier power amplifier and a peaking power amplifier and a method for controlling the Doherty power amplifier.

FIG. 4 is a diagram illustrating a Doherty power amplifier according to an exemplary embodiment of the present invention.

Referring to FIG. 4, the Doherty power amplifier 400 includes a signal separation unit 405, a carrier power amplifier 410, a peaking power amplifier 415 and a combiner 420.

The signal separation unit 405 may be implemented by any one of an analog method and a digital method.

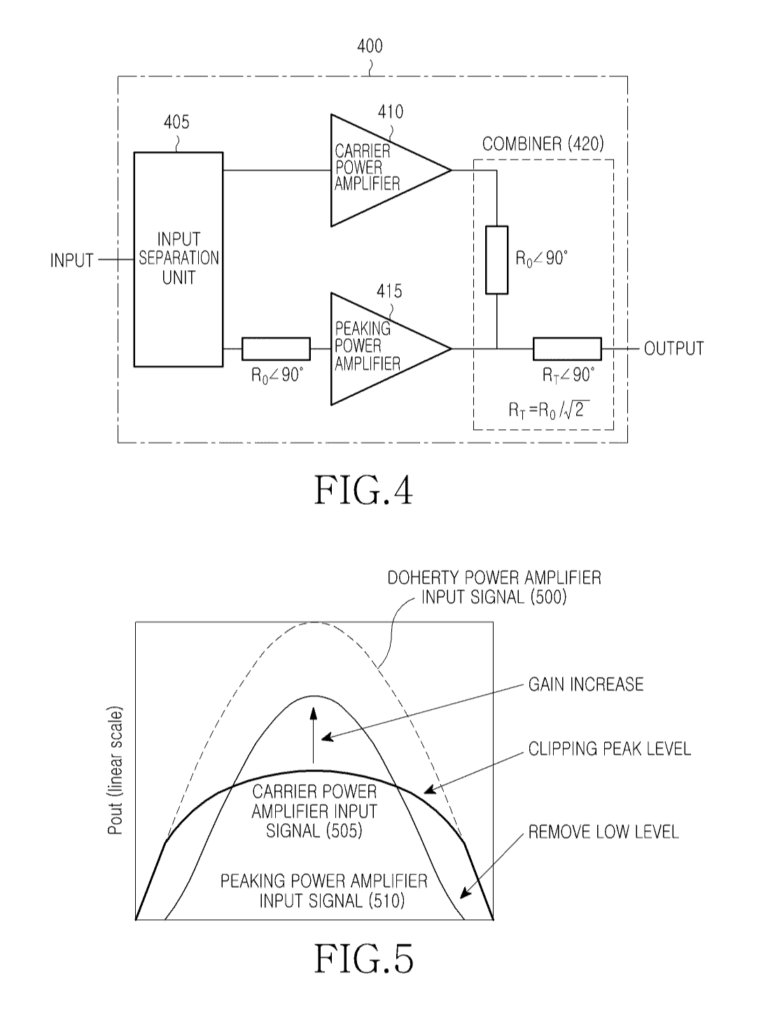

FIG. 5 is a graph illustrating an output signal of a signal separation unit according to an exemplary embodiment of the present invention.

Referring to FIG. 5, the signal separation unit 405 adjusts an input signal 500 applied to the Doherty power amplifier 400 corresponding to each characteristic of the carrier power amplifier 410 and the peaking power amplifier 415, and outputs the adjusted input signal 500 as a carrier power amplifier input signal 505 and a peaking power amplifier input signal 510. The signal separation unit 405 clips the signal in a peak level that is an unnecessary signal of the carrier power amplifier 410 among the Doherty power amplifier input signal 500 and outputs the clipped signal as the carrier power amplifier input signal 505. Therefore, the carrier power amplifier 410 receives the carrier power amplifier input signal 505 of a smaller size than that of the input signal of the existing carrier power amplifier and is operated. Therefore, the carrier power amplifier 410 capacity decreases in comparison with an existing carrier power amplifier, and thus operation efficiency of the carrier power amplifier 410 increases.

In order to remove a signal less than a threshold level from the Doherty power amplifier input signal 500 or compensate the peaking power amplifier 415 gain that is relatively lower than that of the carrier power amplifier 410, the signal separation unit 405 increases the amplitude of the Doherty power amplifier input signal 500 to be higher than that of the carrier power amplifier input signal 505 and outputs the input signal 500 as the peaking power amplifier input signal 510. At this time the threshold level is set as a level of the input signal corresponding to a turn-on point when the peaking power amplifier 415 is ideally operated.

Therefore, the peaking power amplifier 415 receives the peaking power amplifier input signal 510 and is operated so that it prevents unnecessary amplification of a removed low-level signal and compensates low gain, thereby improving efficiency and linearity of the peaking power amplifier 415.

The operations of the Doherty power amplifier 400, except for the carrier power amplifier 410 and the peaking power amplifier 415 receiving the output of the signal separation unit 405 adjusted corresponding to the respective characteristic from the signal separation unit 405, are substantially identical to the conventional Doherty power amplifier. Accordingly, a detailed description thereof will be omitted.

In an exemplary implementation, a method and an apparatus for improving the linearity of the Doherty power amplifier, in which a linearizer for compensating each linearity is separately included to independently linearize an output of the carrier power amplifier and the peaking power amplifier are provided.

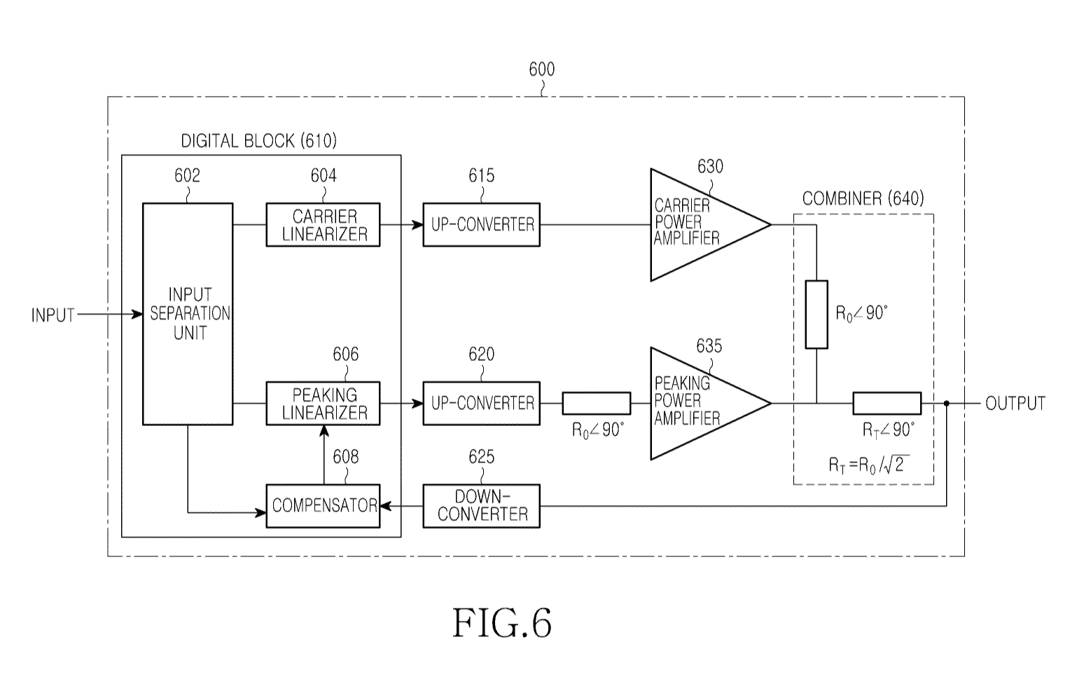

FIG. 6 is a diagram illustrating a Doherty power amplifier according to an exemplary embodiment of the present invention.

Referring to FIG. 6, the Doherty power amplifier 600 includes a digital block 610, a first up-converter 615 and a second up-converter 620, a down-converter 625, a carrier power amplifier 630, a peaking power amplifier 635 and a combiner 640. The remaining structures, except for the digital block 610, of the Doherty power amplifier 600 are substantially identical to the structures of the conventional Doherty power amplifier. Accordingly, a detailed description thereof will be omitted.

The digital block 610 includes a signal separation unit 602 for outputting the input signal corresponding to each characteristic of the carrier power amplifier 630 and the peaking power amplifier 635, a carrier linearizer 604 for independently linearizing each output of the carrier power amplifier 630 and the peaking power amplifier 635, a peaking linearizer 606 and a compensator 608.

Each structure included in the digital block 610 is in a state for linearizing using a training signal before the input signal of the Doherty power amplifier 600 is actually applied. That is, the digital block 610 obtains a carrier linear compensation value and a peaking linear compensation value that independently compensates each distortion generated by an amplification operation of the carrier power amplifier 630 and peaking power amplifier 635 through the training signal. At this time, any step for obtaining the carrier linear compensation value and peaking linear compensation value is performed and then other steps are performed, regardless of sequence.

Steps for linearizing using the training signal according to an exemplary embodiment of the present invention are described in more detail below.

More particularly, a signal separation unit 602 separates the training signal in a same manner as the signal separation unit 405 of FIG. 4. That is, the signal separation unit 602 outputs a signal generated by clipping a signal of a peak level of the training signal according to the carrier power amplifier 630 characteristic as a carrier input signal that is an input signal of the carrier linearizer 604.

Further, the signal separation unit 602 outputs the signal generated by removing a signal less than a threshold level from the training signal according to the peaking power amplifier 635 characteristic or compensating the gain relatively lower than the gain of the carrier linearizer for the training signal as a peaking input signal that is an input signal of the peaking linearizer 606. If the signal separation unit 602 transfers the generated carrier input signal and the peaking input signal to the compensator 608, the compensator 608 then stores the transferred signals.

If the step for obtaining the carrier linear compensation value is performed first, the signal separation unit 602 first outputs the generated carrier input signal to the carrier linearizer 604 and does not output the generated peaking input signal to the peaking linearizer 606. Therefore, during the obtaining of the carrier linear compensation value for compensating distortion generated due to an amplification operation of the carrier power amplifier 630 with respect to the carrier input signal, the operation of the structures connected to the peaking power amplifier 635 is temporarily interrupted.

The carrier input signal is an initial input so that the carrier linearizer 604 outputs the carrier input signal to the first up-converter 615 without performing the linearization. The first up-converter 615 Radio Frequency (RF) converts the carrier input signal to output the converted signal to the carrier power amplifier 630. The carrier power amplifier 630 amplifies the RF converted carrier input signal using a corresponding Direct Current (DC) bias and then outputs the amplified signal to the combiner 640. Therefore, there is no signal applied from the peaking power amplifier 635 so that the combiner 640 outputs to the down-converter 625 a carrier power amplifier output signal experiencing an impedance matching the impedance of the conventional combiner. The down-converter 625 restores the carrier power amplifier RF output signal into a baseband frequency and transfers the restored signal to the compensator 608. The compensator 608 linear compensates the restored carrier power amplifier output signal using a default compensation value. Thereafter, the compensator 608 compares the carrier input signal with the linear compensated carrier power amplifier output signal and obtains the linearity of the restored carrier power amplifier output signal. The compensator 608 compares the obtained linearity with a predefined linearity error threshold. As a result of the comparison, if the obtained linearity is equal to or less than the linearity error threshold, the compensator 608 determines the obtained linearity as a carrier linear compensation value for linear compensation of the distortion generated through the amplification operation of the carrier power amplifier 630 and outputs the determined carrier linear compensation value to the carrier linearizer 604. The carrier linearizer 604 receiving the determined carrier linear compensation value stores the carrier linear compensation value.

As the result of the comparison, if the obtained linearity exceeds the linearity error threshold, the compensator 608 updates the pre-stored carrier linear compensation value. The carrier linear compensation value is updated through sequentially updating a plurality of default compensation values whenever the carrier linear compensation value exceeds the linearity error threshold according to the comparison result. In addition, a default compensation value may be updated in various manners. Thereafter, the compensator 608 executes the carrier linear compensation using the updated compensation value and compares the obtained linearity with the linearity error threshold. The update is repeated until the linearity equal to or less than the linearity error threshold is obtained. If the linearity equal to or less than the linearity error threshold is obtained, the update is completed.

If the step of obtaining the peaking linear compensation value is performed first, the signal separation unit 602 outputs the generated peaking input signal to the peaking linearizer 606 and does not output the generated carrier input signal to the carrier linearizer 604. Therefore, during the obtaining of the peaking linear compensation value for compensating the distortion generated by the amplification operation of the peaking power amplifier 635 for the peaking input signal, the constructions connected to the carrier power amplifier 630 are temporarily interrupted.

The peaking input signal is the initial input so that the peaking linearizer 606 transfers the peaking input signal to the second up-converter 620 without performing the linearizing. The second up-converter 620 RF converts the peaking input signal and the RF converted signal is transferred to the peaking power amplifier 635 after passing through a general impedance matching device.

The peaking power amplifier 635 amplifies the impedance matched peaking input signal using the corresponding DC bias and outputs the amplified signal to the combiner 640. There is no signal applied from the carrier power amplifier 630 so that the combiner 640 outputs to the down-converter 625 the peaking power amplifier output signal experiencing the impedance matching same as the conventional combiner. The down-converter 625 restores the combined signal into the frequency prior to the RF conversion and outputs the restored signal to the compensator 608.

The compensator 608 linear compensates the restored output signal of the carrier power amplifier using the default compensation value. The compensator 608 then obtains the linearity of the peaking power amplifier output signal that is linear compensated in comparison with the peaking input signal. The compensator 608 compares the obtained linearity with the predefined linearity error threshold. If the obtained linearity is less than the linearity error threshold according to the comparison result, the compensator 608 determines the obtained linearity as the peaking linear compensation value that linear compensates the distortion generated through the amplification operation of the peaking power amplifier 635 and transfers the determined peaking linear compensation value to the peaking linearizer 606. The peaking linearizer 606 receiving the determined peaking linear compensation value pre-stores the peaking linear compensation value. If the obtained linearity exceeds the linearity error threshold according to the comparison result, the compensator 608 updates the pre-stored peaking linear compensation value. The peaking linear compensation value is updated by sequentially updating a plurality of default compensation values whenever the peaking linear compensation value exceeds the linearity error threshold according to the comparison result. In addition, the default compensation value may be updated in various manners. Thereafter, the compensator 608 executes the peaking linear compensation using the updated compensation value and compares the obtained linearity with the linearity error threshold. The update is repeated until the linearity equal to or less than the linearity error threshold is obtained. If the linearity equal to or less than the linearity error threshold is obtained, the update is completed.

If the input signal is applied to the Doherty power amplifier 600, the carrier linearizer 604 and the peaking linearizer 606 independently perform the linear compensation for the carrier input signal and the peaking input signal output from the signal separation unit 602, respectively.

In order to obtain the carrier linear compensation value and the peaking linear compensation value for the independent linearization according to an exemplary embodiment of the present invention, step A for obtaining a carrier linear compensation value for linear compensating the distortion generated through the amplification operation of the carrier power amplifier 630 by the carrier linearizer 604 and step B for obtaining the peaking linear compensation value for linear compensating the distortion generated through the amplification operation of the peaking power amplifier 635 by the peaking linearizer 606 must be performed first. At this time, any one of step A and step B may be performed first and the other step may then be performed, regardless of the sequence. Here, step A is performed first and will be described in more detail below.

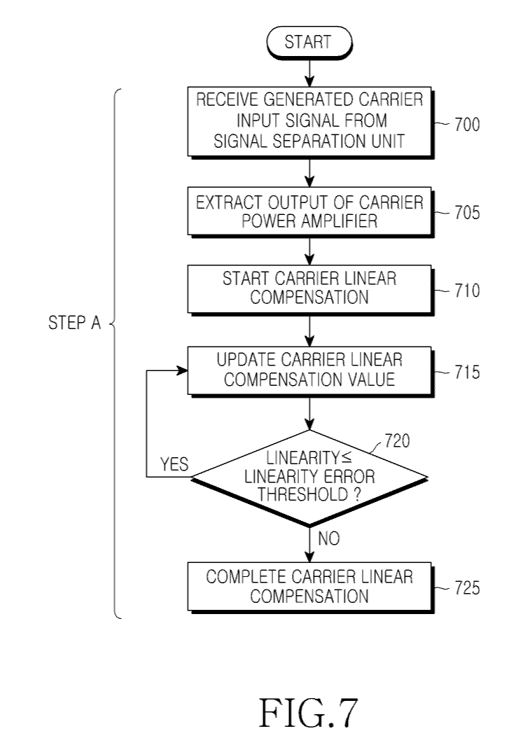

FIG. 7 is a flowchart illustrating steps for obtaining a carrier linear compensation value in a digital block according to an exemplary embodiment of the present invention.

Referring to FIG. 7, the carrier linearizer 604 receives the carrier input signal output from the signal separation unit 602 in step 700. The carrier input signal is generated through clipping the peak level signal that is an unnecessary signal less than the threshold level in the training signal. At this time, the signal separation unit 602 outputs the carrier input signal to the compensator 608. The compensator 608 pre-stores the carrier input signal. The compensator 608 extracts the output signal of the carrier power amplifier 630 from the combiner 640 in step 705. At this time, the signal separation unit 602 is in the state of not-applying the input signal to the peaking power amplifier 635 so that the combiner 640 outputs the existing output signal of the carrier power amplifier 630. The output signal of the carrier power amplifier 630 is the carrier input signal that is power-amplified corresponding to the amplification gain set in the carrier power amplifier 630. The compensator 608 executes a linear compensation algorithm in step 710. That is, the compensator 608 linear compensates the output signal of the carrier power amplifier 630 using a default compensation value and stores the default compensation value as a carrier linear compensation algorithm compensation value in step 715.

The compensator 608 determines the linearity of the linear compensated output signal of the carrier power amplifier 630 using the default compensation value with respect to the pre-stored carrier amplifier input signal and compares the determined linearity with the predefined linearity error threshold in step 720. If the determined linearity is equal to or less than the linearity error threshold according to the comparison result, the compensator 608 determines that the carrier linear compensation algorithm is complete in step 725. That is, the compensator 608 determines the default value as the compensation value for the carrier linear compensation and transfers the determined compensation value to the carrier linearizer 604.

If the determined linearity exceeds the linearity error threshold according to the comparison result, the compensator 608 returns to step 715 to update the default compensation value. For example, a plurality of predefined compensation values may exist and the compensator 608 sequentially updates the default compensation value. In addition, the default compensation value may be updated in various manners.

As described above, if the compensator 608 obtains the compensation value that provides the linearity obtained by the compensator 608 to be less than the predefined linearity error threshold through steps 700 to 720, the compensator 608 determines the obtained compensation value as the carrier linear compensation value to complete the carrier linear compensation.

The case where step B is performed will be described in more detail below.

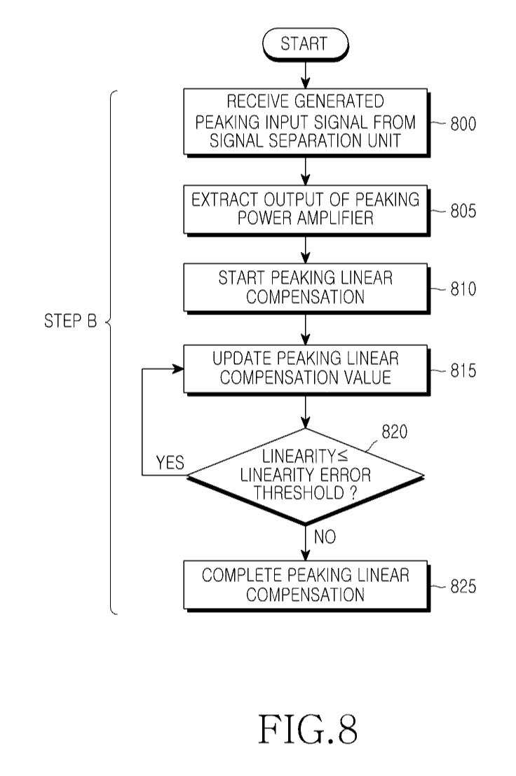

FIG. 8 is a flowchart illustrating steps for obtaining a peaking linear compensation value in a digital block according to an exemplary embodiment of the present invention.

Referring to FIG. 8, the peaking linearizer 604 receives the peaking input signal from the signal separation unit 602 in step 800. The peaking input signal is generated by removing the signal less than the threshold level from the training signal or compensating the gain relatively lower than that of the carrier linearizer for the training signal. At this time, the signal separation unit 602 outputs the peaking input signal to the compensator 608 and the compensator 608 pre-stores the peaking input signal. The compensator 608 extracts the output signal of the peaking power amplifier 635 from the combiner 640 in step 805. At this time, the signal separation unit 602 is in a state of not-applying the input signal to the carrier power amplifier 635 so that the combiner 640 outputs the existing output signal of the peaking power amplifier 635. The output signal of the peaking power amplifier 635 is the peaking input signal power-amplified corresponding to the amplification gain set in the peaking power amplifier 635.

The compensator 608 executes a linear compensation algorithm in step 810. That is, the compensator 608 linear compensates the output signal of the peaking power amplifier 635 using the default compensation value and stores the default compensation value as a carrier linear compensation algorithm compensation value in step 815.

The compensator 608 determines the linearity of the linear compensated output signal of the peaking power amplifier 635 using the default compensation value with respect to the pre-stored peaking amplifier input signal and compares the determined linearity with the predefined linearity error threshold in step 820. If the determined linearity is equal to or less than the linearity error threshold according to the comparison result, the compensator 608 determines that the peaking linear compensation algorithm is complete in step 825. That is, the compensator 608 determines the default value as the compensation value for the peaking linear compensation and transfers the determined compensation value to the peaking linearizer 606.

If the determined linearity exceeds the linearity error threshold according to the comparison result, the compensator 608 returns to step 815 to update the default compensation value. For example, a plurality of predefined compensation values exist and the compensator 608 sequentially updates the default compensation value. In addition, the default compensation value may be updated in various manners.

As described above, if the compensator 608 obtains the compensation value that provides the linearity obtained by the compensator 608 to be less than the predefined linearity error threshold through steps 800 to 820, the compensator 608 determines the obtained compensation value as the peaking linear compensation value to complete the peaking linear compensation.

The input signal separation unit according to exemplary embodiments of the present invention provide a carrier power amplifier and a peaking power amplifier with an input signal in which an unnecessary peak level signal is clipped or the input signal in which an unnecessary low level signal is removed to enhance performance of an entire system, respectively. Accordingly, the carrier power amplifier and the peaking power amplifier capacity are minimized and efficiency is maximized. Further, a linearizer capable of independently linearizing the carrier power amplifier and peaking power amplifier, respectively, is provided so that linearity of a Doherty amplifier can be advantageously improved.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. An apparatus for enhancing performance of a Doherty power amplifier, the apparatus comprising:
a signal separation unit for generating a first input signal serving as an input signal of a carrier power amplifier using an input signal and a second input signal serving as an input signal of a peaking power amplifier using the input signal,
wherein the first input signal is different from the second input signal.

2. The apparatus as claimed in claim 1, wherein the signal separation unit clips a peak level signal of the input signal to generate the first input signal and removes a signal less than a threshold level from the input signal to generate the second input signal.

3. The apparatus as claimed in claim 2, wherein the threshold level is set as a level of an input signal that turns on the peaking power amplifier if the peaking power amplifier is ideally operated.

4. The apparatus as claimed in claim 1, wherein the signal separation unit increases amplitude of the input signal by a predefined level for compensating gain of the peaking power amplifier that is lower than the gain of the carrier power amplifier, to generate the second input signal.

5. The apparatus as claimed in claim 1, wherein the signal separation unit outputs the first input signal to the carrier power amplifier and the second input signal to the peaking power amplifier.

6. The apparatus as claimed in claim 1, wherein the signal separation unit outputs at least one of the first input signal to the carrier power amplifier and the second input signal to the peaking power amplifier.

7. The apparatus as claimed in claim 6, further comprising a compensator for determining a first linear compensation value for compensation of linearity of the carrier power amplifier and a second linear compensation value for the compensation of linearity of the peaking power amplifier.

8. The apparatus as claimed in claim 7, further comprising:
a first linearizer for linear compensating the first input signal using the first linear compensation value; and
a second linearizer for linear compensating the second input signal using the second linear compensation value.

9. A method for enhancing performance of a Doherty power amplifier, the method comprising:
generating a first input signal serving as an input signal of a carrier power amplifier using an input signal; and
generating a second input signal serving as an input signal of a peaking power amplifier using the input signal,
wherein the first input signal is different from the second input signal.

10. The method as claimed in claim 9, wherein the first input signal is a signal in which a peak level signal of the input signal is clipped and the second input signal is a signal in which a signal less than a threshold level is removed from the input signal.

11. The method as claimed in claim 10, wherein the threshold level is set as a level of an input signal that turns on the peaking power amplifier if the peaking power amplifier is ideally operated.

12. The method as claimed in claim 9, wherein the second input signal is a signal in which an amplitude of the input signal is increased by a predefined level for compensating gain of the peaking power amplifier that is relatively lower than the gain of the carrier power amplifier.

13. The method as claimed in claim 9, further comprising outputting the first input signal to the carrier power amplifier and the second input signal to the peaking power amplifier.

14. The method as claimed in claim 13, further comprising outputting the first input signal to the carrier power amplifier or the second input signal to the peaking power amplifier.

15. The method as claimed in claim 14, further comprising determining a first linear compensation value for compensating linearity of the carrier power amplifier and a second linear compensation value for compensating linearity of the peaking power amplifier.

16. The method as claimed in claim 15, further comprising:
linear compensating the first input signal using the first linear compensation value; and
linear compensating the second input signal using the second linear compensation value.

17. An apparatus comprising a digital block for linearizing in a Doherty power amplifier, the digital block comprising:
a signal separation unit for generating an input signal corresponding to characteristics of a carrier power amplifier and a peaking power amplifier, and for outputting a first input signal to the carrier power amplifier and a second input signal to the peaking power amplifier;
a carrier linearizer for independently linearizing the output of the carrier power amplifier;
a peaking linearizer for independently linearizing the output of the peaking power amplifier; and
a compensator for determining a first linear compensation value for compensation of linearity of the carrier power amplifier and a second linear compensation value for the compensation of linearity of the peaking power amplifier.

18. The digital block of claim 17, wherein the signal separation unit clips a peak level signal of the input signal to generate the first input signal and removes a signal less than a threshold level from the input signal to generate the second input signal.

19. The digital block of claim 18, wherein the threshold level is set as a level of an input signal that turns on the peaking power amplifier if the peaking power amplifier is ideally operated.

20. The digital block of claim 17, wherein the signal separation unit increases amplitude of the input signal by a predefined level for compensating gain of the peaking power amplifier that is lower than the gain of the carrier power amplifier, for generating the second input signal.
